(19) United States
(12) Patent Application Publication
(10) Pub. No.: US 2007/0201259 A1
(43) Pub. Date: Aug. 30, 2007

(54) Method and Apparatus for Programming and Reading Codes on an Array of Fuses

(75) Inventor: Leon Van Gorsel, Almere (NL)

Correspondence Address: EDELL, SHAPIRO & FINNAN, LLC, 1901 RESEARCH BOULEVARD, SUITE 400, ROCKVILLE, MD, 20850, US

(73) Assignee: CAVENDISH KINETICS LIMITED, Hertfordshire (GB)

(21) Appl. No.: 11/681,528

(22) Filed: Mar. 2, 2007

Related U.S. Application Data
(63) Continuation of application No. PCT/GB05/03369, filed on Aug. 31, 2005.

(30) Foreign Application Priority Data
Sep. 2, 2004 (GB) 0419465.0

(51) Int. Cl. G11C 17/00

(52) U.S. Cl. 365/96

(57) ABSTRACT

An device for programming and reading codes onto an array of binary data storage element includes: a shift register for receiving, sequentially, a binary data series to be written onto the data storage elements; and control logic circuit for determining whether or not data is to be applied to each of the data storage elements in turn, by reading sequentially the data stored in the shift register and if it is determined that data is to be stored on a respective data element, applying a write signal to that data element. The control logic circuit applies a permanent locking signal to the array of data storage elements such that further writing to the elements is prohibited when it has been determined that data has been written to each of the elements which require data to be written thereto.

### CROSS REFERENCE TO RELATED APPLICATIONS

This application is a continuation of International Application No. PCT/GB2005/003369, filed on Aug. 31, 2005, entitled “Method and Apparatus for Programming and Reading Codes on an Array of Fuses,” which claims priority under 35 U.S.C. §119 to Application No. GB 0419465.0 filed on Sep. 2, 2004, entitled “Method and Apparatus for Programming and Reading Codes on an Array of Fuses,” the entire contents of which are hereby incorporated by reference.

### FIELD OF THE INVENTION

The present invention relates to the programming and reading of a chip identity (CHIP ID) using semiconductor fuses, in particular, but not exclusively, in nonvolatile memory devices.

### BACKGROUND

Semiconductor memories may be programmed using, for example, semiconductor fuses which are sent to indicate data to be stored. Previous solutions have tended to rely on a fixed large program time per fuse, or alternatively, lasers have been used to program the fuses, but laser programming has the problem that its use to set chip codes tends to be very slow.

### SUMMARY

The present invention offers a non volatile, programmable read only array which can be programmed once, and read out multiple times. The size of the array can be selected. To prevent reprogramming of the array, a locking mechanism can be provided. Access to the array is established by using a shift register. The programming can be performed with only a single supply voltage of, for example, 3.3V. With the invention the required programming current per bit can be as low as 3 mA. The bit cell contains a fuse which is based on MEMS technology on top of standard CMOS processing. This solution is used to program fuses for large Chip ID's, e.g., 128 bits, as fast as possible.

According to the present invention there is provided an apparatus for programming and reading codes onto an array of binary data storage elements, the apparatus comprising:

a shift register for receiving, sequentially, a binary data series to be written onto the data storage elements; and

control logic circuit arranged to determine whether or not data is to be applied to each of the data storage elements in turn by reading sequentially the data stored on the shift register and applying, if it is determined that data is to be stored on a respective data element, applying a write signal to that data element, the control logic circuit further comprising means for applying a permanent locking signal to the array of data storage elements as such that further writing to the elements is prohibited when it has been determined that data has been written to each of the elements which require data to be written thereto.

Some of the distinguishing features of the invention include: non volatility; the fact that it is one time programmable in the field; it can operate with clock frequencies up to 100 MHz for read mode and operate with clock frequencies up to 1 MHz for program mode; it can use a single voltage supply and does not require any other high voltages; it has a small bit cell size; the number of ID bits is selectable up to 256 bits or higher in steps of 1 bit; it can interface via a synchronous shift register; it has a maximum programming time up to 10 μs per bit (with a 1 MHz. program clock); and can be fabricated on top of CMOS as thin as 0.35 μm.

The present invention overcomes the limitations of the prior art and affords faster chip identification programming times for the complete chip ID. This is achieved by iterative access to fuses in an array with the use of a predetermined period of time to assess whether a fuse has been blown or not before sampling the next fuse.

The present invention also has lower power dissipation for programming the complete chip ID. This is achieved by having the fuses blown one-at-a-time as opposed to blowing fuses simultaneously in accordance with solutions of the prior art.

An additional advantage in its lower cost, caused by shorter tester usage time.

The above and still further features and advantages of the present invention will become apparent upon consideration of the following definitions, descriptions and descriptive figures of specific embodiments thereof wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

An example of the present invention will now be described with reference to the accompanying drawings, in which:

FIG. 1 is a schematic block diagram showing a chip identification circuit according to an exemplary embodiment of the present invention;

FIG. 2A is a timing diagram showing the timing of control signals within the circuitry of FIG. 1;

FIG. 2B is a schematic diagram showing the construction of the shift register of FIG. 1;

FIG. 3 is a schematic circuit diagram showing the fuse array of FIG. 1;

FIG. 4 is a flow chart showing the operation of the circuit of FIG. 1 during data writing;

FIG. 5 is a flow diagram showing the overall operation of the circuit of FIG. 1; and

FIGS. 6 and 7 are timing diagrams showing operation of the circuit of FIG. 1 during a writing and a reading operation respectively.

### DETAILED DESCRIPTION

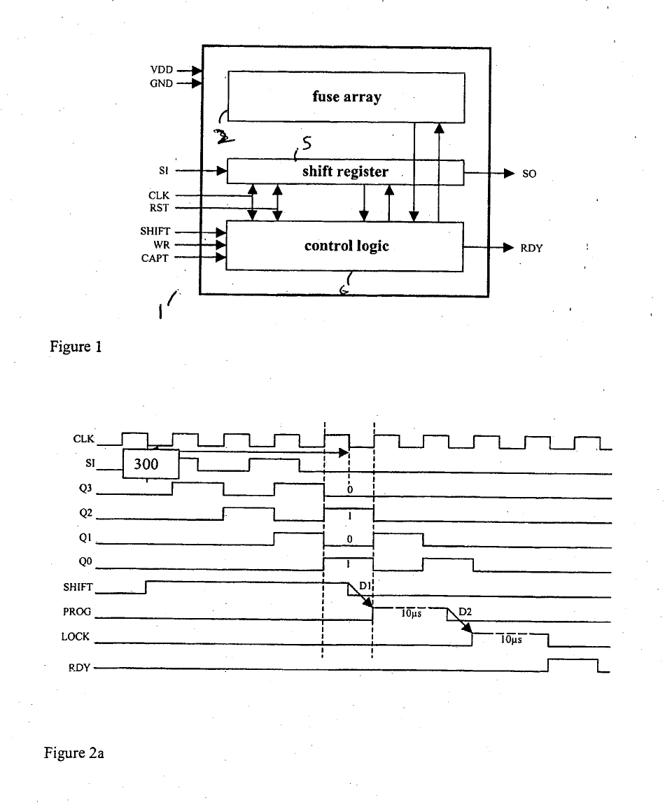

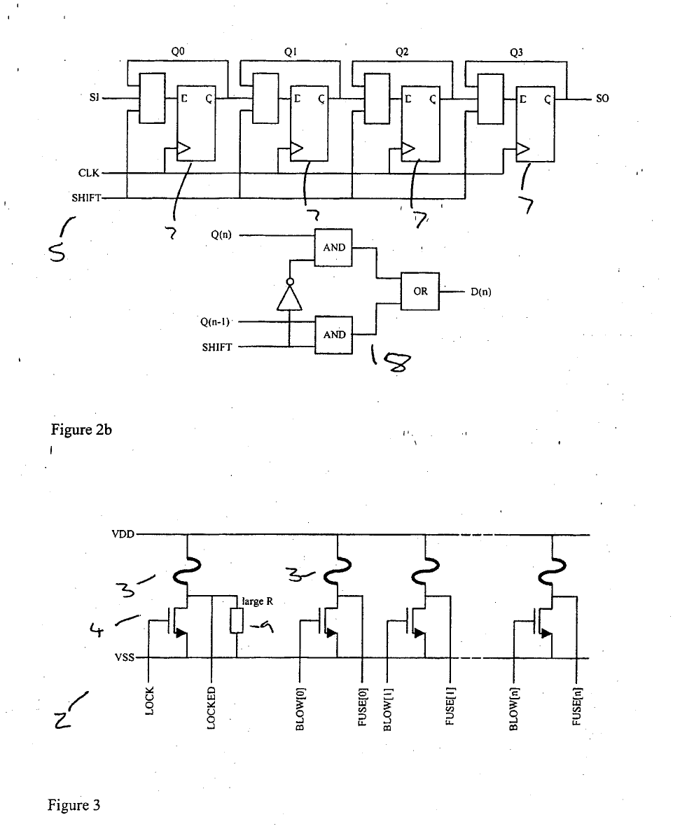

FIG. 1 shows the three main blocks of a chip identification circuit according to the invention. Referring to FIG. 1, an apparatus 1 according to the present invention is arranged to program and read codes on a chip, such codes storing data that confirm an identification code for the chip. The apparatus 1 comprises an array of fuses 2, the blown or un-blown nature of each fuse 3 (see FIG. 3) representative of a “0” or a “1” in the data code to be stored. As can also be seen from FIG. 3, each fuse 3 has an associated transistor 4 which can receive signals to enable its respective views 3 to be blown as required. The apparatus 1 also comprises a shift register 5 which is shown in more detail in FIG. 2B. Linked with the shift register 5 is control logic 6 which provides control signals to the shift register 5. Those control signals will be described further below and an example timing for the signal is shown in FIGS. 2A and 6 and 7.

An object of the present invention is to impart on a chip a n-bit identity code in the form bn: b0, b1 . . . bn-1. In the example of the present invention in FIG. 1, an eight bit code is to be assigned to the chip, for example, 10110100 (b7, . . . b0). To assign this chip ID code onto the chip, two primary procedures must be undertaken, namely, programming the chip ID and reading out the chip ID. This can be achieved after processing, i.e., after the fabrication of the wafers in the factory; or in the field wherein the chip ID is used in an application such as a mobile cellular device (after processing or in the field). The first of the procedures occurs in three phases.

The present invention enables the user to have program and read access on a chip ID, after processing or during operation in the field. In most of the cases, the chip ID is programmed after processing, so in the field only the read action will be performed.

The order in which the application is used is:
1. program the chip ID;
2. read out the chip ID

The programming procedure of the present invention comprises three phases:
1. Shift in the chip ID data/code;
2. program/blow the fuses which need to be programmed/blown; and
3. lock the program/blow mechanism.

In the example of the present invention, binary digits are used to indicate the state of a fuse. For example, arbitrarily ‘1’ designates a fuse that is not blown or should not be blown, while a ‘0’ designates a fuse that is to be blown or has been blown. This could, of course, be reversed. During a first phase of the programming procedure, the chip ID data/code is shifted into the serial shift registers. This achieved by applying a Clock (CLK), SHIFT, and Serial In (SI) signal to the input pin of the catenation of fuses associated with the corresponding ones of flip-flop circuits 7. This permits data to be shifted in one bit at a time synchronously with a clock (CLK) signal. Each bit is associated with a flip-flop and a corresponding multiplexer 8 as shown in the schematics of FIGS. 2a and 2b, wherein the output of each flip flop 7 is connected to the input of the next flip-flop 7 in the cascade 5. As one bit is moved into the first flip flop, other bits stored in the register all move one place. FIG. 3 shows the fuses 3 and circuitry to ensure that they are blown. FIG. 3 also shows, on the first transistor 4 in the fuse array 2, a large resistance 9 associated therewith which enables the provision of a locking signal, the functionality of which will be described below.

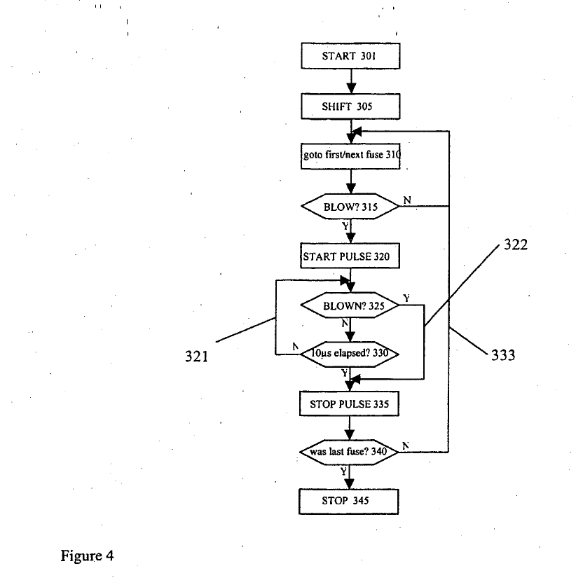

After the serial shift procedure described hereinbefore, phase 2 of the programming procedure is initiated wherein the chip ID stored in the serial shift registers is programmed into the fuses 3. Referring to the flow chart in FIG. 4, a predetermined period of time is required to blow the fuse. For example the control logic 6 can be set such that 10 μs as a maximum is needed to blow/program a fuse. By looking to the first ID-bit in the serial shift register, the control logic 6 determines if the fuse should be blown/programmed or not, based on the value of the ID-bit (1 or 0) as described hereinbefore. When there is no need to blow/program this fuse, the algorithm will examine the next ID-bit, until all bits are examined. In case the fuse should be programmed/blown, the control logic 6 will put a program pulse on the fuse, and will check if the fuse is blown before the required period (10 μs) are elapsed. If the fuse is blown before the required 10 μs has elapsed, the algorithm will directly go to the next fuse. When the fuse is not programmed/blown before the required 10 μs have elapsed the algorithm will automatically go to the next fuse, to prevent the system from a hang-up situation. The algorithm may then flag that there is a problem so that the chip can be rejected, inspected, or undergo further processing as required. When all fuses are examined the algorithm will go to phase 3.

The following steps are therefore undertaken. First, the ID code is serially shifted into the registers. When the shift is finished, the system should identify if the first fuse should be blown. When the fuse should not be blown, identify if the next fuse should be blown. When a fuse should be blown, set a pulse on the gate of the blow transistor; check during this period if the fuse has been blown before the end of the period; if that is the case, shut off the pulse, and identify if the next fuse should be blown. If, after a given period (say 10 μs) the fuse has not yet blown, then note that there is a problem but proceed and identify if the next fuse should be blown.

During phase 3, a lock is set on the program/blow mechanism to prevent the user from programming/blowing unblown/unprogrammed fuses again. This is done by disabling the program pulse which programs/blows the fuses. The LOCK command, when initiated, locks the entire program mechanism and hence the complete chip ID code onto the chip.

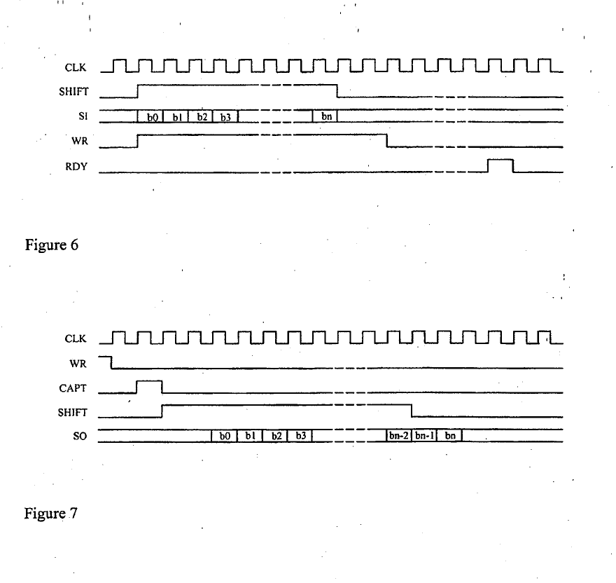

The write cycle signals are shown in FIG. 6. The figure shows the signals which can be used to program the chip ID. The clock (CLK) which should be applied has in this example a frequency of 1 MHz. (period=1 μs). Serial input data (SI) starts with writing bit n (bn) and finish as with bit 0 (b0) from a timing point of view. Serial shift indicator (SHIFT) should be high during the supply of serial input bits. Care should be taken to ensure that SHIFT is active only during an amount of clock cycles which is equivalent to the number of ID bits. To indicate that a write action takes place, a write indicator (WR) is available during the shift cycle, plus two extra clock cycles, to compensate for internal delays. When the write process is finished, a ready indicator (RDY) will inform that the fuses are programmed. There is no problem in WR being available over a longer period of time, but WR should be set to ‘0’ when a read action should be performed. While the frequency of the clock can vary, it will be appreciated that the internal counter should be designed to produce an elapsed time signal at the desired fuse period. The frequency should not, however be higher than a maximum value. The time which is needed to program a complete chip ID depends on the number of ID bits [n], the time it takes to blow a fuse, number of clock cycles [b1], the number of fuses that have to be blown (0=blow, 1=not blow) [nb], and the used clock frequency with corresponding period [T_{clk}]. For program times there are 3 cases:

1. all ‘1’: T_{prog}={n+b1+3}T_{clk}

2. all ‘0’: T_{prog}={n+1+nb(b1+1)+nb}T_{clk}

3. else: T_{prog}={n+2+nb(b1+1)+b1}Tclk

To consider some examples:

Assume that T_{clk}=1 μs, and to blow a fuse, 4 clock-cycles are needed, so b1=4.

ID=“0101”→T_{prog}{4+2+2(4+1)+4}1μ=20 μs (type 3)
ID=“11111111”→T_{prog}={8+4+3}1μ=15 μs (type 1)
ID=“000000”→T_{prog}={6+1+6(4+1)+6}1μ=43 μs (type 2)

The reading of the chip ID will now be explained. Reading involves two phases.
1. capture the chip ID data/code in the serial shift register
2. Shift out the chip ID data/code from the serial shift register.

During phase 1, a CAPT (Capture) command is given. This parallel loads the chip ID data/code which is stored in the fuses into the serial shift register.

During phase 2 the chip ID data/code is shifted out of the serial shift register. The serial shift register is of a well known standard design. By applying a CLK (Clock), and SHIFT signal the user is able to shift out data from the serial shift register at the SO (Serial Output) pin.

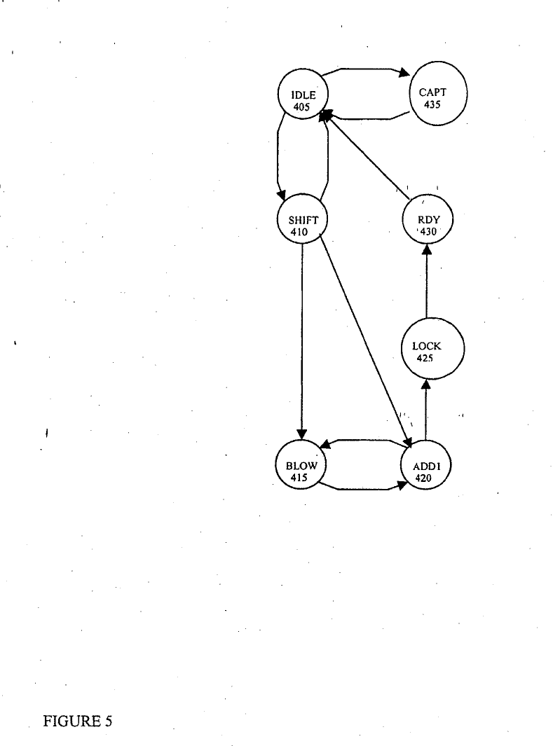

A finite state system 400 operable with the present invention is shown in terms of the flow chart in FIG. 5. Each state may be represented within a state machine having one or more states and triggers that control transitions between different states. In the present invention, the finite state machine comprises a number of states: IDLE 405, SHIFT 410, BLOW 415, ADD1 420, LOCK 425, RDY 430, and CAPT 435.

Now a short explanation will be given for the system 400. The example assumes that the clock will run continuously, the example pattern is: “10110100” (b7 . . . b0), so maxcnt is 7. To give an example running through a whole write cycle, firstly the control logic starts in the IDLE state, then enable wr (write). This opens the path from state SHIFT to the next states.

Shift is enabled for n clock cycles, where n is the number of fuses. In this case n=8. On entering state SHIFT, the count (cnt) will be set to 0, and point to bit b0. Shift is then disabled. With wr=‘1’ and shift=‘0’, the control logic can go to state BLOW or ADD1. In this case, b0 is 0, so the control logic goes to state BLOW. This will open the prog transistor. When the fuse is blown (b1=‘1’), or the timer is elapsed (elap=‘1’), the control logic goes to ADD1.

Now the counter is increased (async) until a bit indicates that it should be set. In this case the counter will increase to value 1, because b1 is set to ‘0’.

Now the control logic 6 will enter state BLOW which will open the driver transistor for fuse b1. When the fuse is blown (b1=‘1’), or the timer has elapsed (elap=‘1’) the control logic 6 goes to ADD1. Jumping between BLOW and ADD1 continues until cnt>=maxcnt (7). Now the control logic 6 goes to state LOCK, which will blow the lock fuse to disable writing. When the fuse is blown, or the timer has elapsed, the control logic 6 goes to state RDY. In state RDY a signal indicates that the write cycle is finished, and the IDLE state is entered again.

The read cycle is now described in connection with FIGS. 5 and 7. Start is again in the IDLE state. Capture high is made high, to capture the current state of the fuses in the shift register. By disabling capture, the process goes back from state CAPT to IDLE. Now it is necessary to keep wr low, to prevent from writing (also lock will disable that path). Shift is enabled for n clockcycles, where n is the number of fuses. In this case, n=8. Shift is then disabled, to return to the IDLE state.

The read cycle signals are shown in FIG. 7. The read cycle starts with the need to be sure that the write indication (WR) is set to ‘0’. Now a capture instruction (CAPT) can be given. At the falling edge of CAPT, the shift operation (SHIFT) can start. With a delay of 2 clock-cycles, data will come out on the serial output (SO). Care should be taken to ensure that SHIFT is active only during an amount of clock-cycles which is equivalent to the number of ID bits. The read time [T_{read}] depends only on the number of bits [n] and the used clock frequency, which has a certain period [T_{clk}].

T_{read}=(n+3)T_{clk}. The number 3 comes from: 1 capture cycle+2 delay cycles.

As will be appreciated from the above, the circuitry of the present invention operates to write the relevant identification codes to the fuses 3 in a systematic and highly efficient manner without the need for laser writing, and provides a circuit which can be incorporated into the chip so that additional circuitry is not required to write the data to the fuses 3. This means that identification writing is fast and efficient and can be performed, if required, in a location other than the manufacturing plant of the chip.

Having described exemplary embodiments of the invention, it is believed that other modifications, variations and changes will be suggested to those skilled in the art in view of the teachings set forth herein. It is therefore to be understood that all such variations, modifications and changes are believed to fall within the scope of the present invention as defined by the appended claims. Although specific terms are employed herein, they are used in a generic and descriptive sense only and not for purposes of limitation.

What is claimed is:

1. An apparatus for programming and reading codes onto an array of binary data storage elements, the apparatus comprising:
a shift register for receiving, sequentially, a binary data series to be written onto the binary data storage elements; and
control logic circuit configured to determine whether or not data is to be applied to each of the data storage elements in turn by sequentially reading data stored on the shift register and applying a write signal to a respective data element in response to determining that data is to be stored on the respective data element,
the control logic circuit applying a permanent locking signal to the array of binary data storage elements such that further writing to the binary data storage elements is prohibited in response to determining that data has been written to each of the elements which require data to be written thereto.

2. An apparatus according to claim 1, wherein the control logic circuit sequentially reads the data stored on each of the data storage elements.

3. An apparatus according to claim 1, where each of the data storage elements comprise individual fuses that can be blown to permanently store binary data thereon.

4. An apparatus according to claim 3, wherein the control logic circuit is configured to apply a write signal to a respective data storage element for a predetermined fixed period of time.

5. An apparatus according to claim 4, wherein the control logic circuit is configured to detect whether or not a fuse has blown when a write signal has been applied for the predetermined period of time, and issues an error signal in response to detecting that any of the respective fuses has not blown during the writing process.

6. A semiconductor chip comprising:
said array of binary data storage elements configured to permanently store data indicating the identity of the semiconductor chip;
and the apparatus according to claim 1.
